(19) United States
(12) Patent Application Publication
(10) Pub. No.: US 2026/0255701 A1
(43) Pub. Date: Aug. 27, 2026

(54) RADIOGRAPHIC IMAGE DETECTOR

(71) Applicant: Konica Minolta, Inc., Tokyo (JP)

(72) Inventors: Yoshito YAMAMOTO, Tokyo (JP); Yasushi NAGATA, Tokyo (JP)

(21) Appl. No.: 19/542,912

(22) Filed: Feb. 18, 2026

(30) Foreign Application Priority Data
Feb. 27, 2025 (JP) 2025-030133

(51) Int. Cl. H10F 39/18; G01T 1/202; H10F 39/00

(52) U.S. Cl. CPC H10F 39/1898; G01T 1/2023; H10F 39/016

(57) ABSTRACT

A radiographic image detector includes a scintillator panel including a substrate, and on a substrate surface of the substrate, a vapor deposition film layer in which a phosphor component is vapor-deposited in a film form together with an activator component. A vapor deposition film thickness corresponding to a thickness of the vapor deposition film layer from the substrate surface is set to a thickness within ±10% with respect to a film thickness median value over an entire surface of the vapor deposition film layer. A film thickness distribution related to the vapor deposition film thickness and an activator concentration distribution related to an activator concentration of the activator component in the vapor deposition film layer correlate with each other.

### CROSS-REFERENCE TO RELATED APPLICATION

The entire disclosure of Japanese Patent Application No. 2025-030133, filed on Feb. 27, 2025, including description, claims, drawings and abstract is incorporated herein by reference.

### BACKGROUND OF THE INVENTION

### Technical Field

The present disclosure relates to a radiographic image detector.

### Description of Related Art

There is known a radiographic image detector (flat panel detector (FPD)) using a radiation detector that converts incident radiation into light such as visible light by a scintillator panel and detects the converted light by photoelectric conversion elements, such as photodiodes, two dimensionally arranged on a substrate. The radiographic image detector further converts the light incident on the photoelectric conversion elements into electric charges and extracts the generated electric charges, thereby detecting, as electrical signals, information held by the emitted radiation through the subject. Radiographic images obtained by such a principle are used in various industrial fields including the medical field.

In the aforementioned radiation detector, the scintillator panel mainly includes a substrate and a scintillator which is a vapor deposition film layer (phosphor film layer) in which a phosphor component is grown as columnar crystals on one substrate surface of the substrate. In the phosphor component, for example, cesium iodide, gadolinium sulfide, or the like serving as a base material of the scintillator is used, and an activator of the scintillator, such as thallium, is included. Scintillator panels having scintillators such as thallium-activated cesium iodide (CsI:Tl) and sodium-activated cesium iodide (CsI:Na), in each of which the base material of the scintillator and the activator are vapor-deposited on the substrate surface using a vapor phase growth method, are known (see Japanese Unexamined Patent Publication No. 2004-63272, Japanese Unexamined Patent Publication No. 2021-94076, Japanese Unexamined Patent Publication No. 2018-9803, etc.). A scintillator is a substance that absorbs radiation such as X-rays and emits light, is mainly used in a radiation detector, and has the function of converting, when radiation hits the scintillator, the energy of the radiation into light.

In the scintillator panel of the radiation detector, it is known that the film thickness of a vapor deposition film layer greatly contributes to the luminance which is the brightness per unit area of the light converted by the scintillator panel. Therefore, in the formation of a vapor deposition film layer of a scintillator panel, it is required to finely control vapor deposition conditions of a phosphor component such as cesium iodide and to form a vapor deposition film layer having a uniform film thickness distribution without a bias in film thickness.

### SUMMARY OF THE INVENTION

However, the vapor deposition film layer is mainly formed by the vapor phase growth method as described above, and it is necessary to form the vapor deposition film layer while gradually crystal-growing the phosphor component vaporized from the evaporation source on the substrate surface. Therefore, there is a possibility that the film thickness distribution of the vapor deposition film layer is biased. In particular, in a case where a vapor deposition film layer having a large vapor deposition area (e.g., a size equal to or larger than a 500 mm×500 mm) is formed by the vapor phase growth method, there is a possibility that a large bias occurs in the film thickness distribution. Accordingly, there is a possibility that the luminance distribution of luminance in the scintillator panel (vapor deposition film layer) is not uniform.

Many attempts and techniques have been proposed for forming a vapor deposition film layer having a uniform film thickness distribution by utilizing the vapor phase growth method. For example, a vapor deposition method is performed in which a phosphor component is vaporized from an evaporation source disposed on a substrate surface side while a substrate as a vapor deposition target is rotated at a predetermined number of rotations. Furthermore, a method in which evaporation sources are arranged at predetermined intervals to control the vapor deposition amount of a phosphor component to be vapor-deposited on a substrate surface and a method in which the distance between a substrate surface and an evaporation source is increased to equalize the vapor deposition amount of a phosphor component on the substrate surface are known.

However, in the above-described vapor deposition methods, complicated control is required in some cases in order to form a vapor deposition film thickness formed with a uniform film thickness distribution. Furthermore, using a plurality of evaporation sources or making the distance between the substrate and the evaporation source long may increase the usage amount of the phosphor component, such as cesium iodide, used as a raw material. In particular, making the distance between the substrate surface and the evaporation source long results in only a portion of the phosphor component evaporated and transpired from the evaporation source being vapor-deposited on the substrate surface, and there is a possibility that the other portion of the phosphor component not used in the vapor deposition is wasted. Therefore, the utilization rate of the phosphor component decreases, and the raw material cost may increase in the formation of the vapor deposition film layer.

In consideration of the above-described circumstances, an object of the present disclosure is to provide a radiographic image detector including a scintillator panel capable of forming a vapor deposition film layer having a large vapor deposition area while achieving uniformity of luminance distribution in the scintillator panel and, in particular, suppressing the formation cost.

To achieve at least one of the abovementioned objects, according to an aspect of the present disclosure, a radiographic image detector reflecting one aspect of the present disclosure includes a scintillator panel including:
a substrate; and
on a substrate surface of the substrate, a vapor deposition film layer in which a phosphor component is vapor-deposited in a film form together with an activator component,
wherein a vapor deposition film thickness corresponding to a thickness of the vapor deposition film layer from the substrate surface is set to a thickness within ±10% with respect to a film thickness median value over an entire surface of the vapor deposition film layer, and
wherein a film thickness distribution related to the vapor deposition film thickness and an activator concentration distribution related to an activator concentration of the activator component in the vapor deposition film layer correlate with each other.

### BRIEF DESCRIPTION OF THE DRAWINGS

The advantages and features provided by one or more embodiments of the invention will become more fully understood from the detailed description given hereinafter and the appended drawings which are given by way of illustration only, and thus are not intended as a definition of the limits of the present disclosure, and wherein:

FIG. 1 is an explanatory diagram illustrating a schematic configuration of a radiographic image detector according to the present embodiment;

FIG. 2 is an explanatory diagram schematically illustrating a vapor deposition image related to formation of a vapor deposition film layer;

FIG. 3 is an explanatory diagram schematically illustrating a vapor deposition film thickness, an activator concentration, and a luminance at each position of the vapor deposition film layer of FIG. 2;

FIG. 4 is an explanatory diagram schematically illustrating a film thickness distribution, an activator concentration distribution, and a luminance distribution of a vapor deposition film layer;

FIG. 5 is an explanatory diagram illustrating a film thickness distribution in a concentric semicircular shape;

FIG. 6 is an explanatory diagram showing a film thickness distribution in a concentric quadrantal shape;

FIG. 7 is an explanatory diagram schematically illustrating a vapor deposition film layer of another example configuration having a first vapor deposition film layer and a second vapor deposition film layer;

FIG. 8 is an explanatory diagram schematically illustrating a vapor deposition film layer of another example configuration having a third vapor deposition film layer and a fourth vapor deposition film layer;

FIG. 9 is an explanatory diagram schematically illustrating a vapor deposition image related to formation of a vapor deposition film layer of a comparative example; and

FIG. 10 is an explanatory diagram schematically illustrating a vapor deposition film thickness, an activator concentration, and a luminance at each position of the vapor deposition film layer of FIG. 9.

### DETAILED DESCRIPTION

Hereinafter, one or more embodiments of a radiographic image detector in the present disclosure will be described with reference to the drawings. However, the scope of the present disclosure is not limited to the embodiments or illustrated examples. In addition, the drawings do not necessarily faithfully represent the dimensional ratios of the actual members. Further, in the present specification, the term “phosphor” refers to all substances that convert energy such as radiation from the outside into light, and includes “scintillator” in a broad sense. Furthermore, “cesium iodide” is a base material of the scintillator, whereas “thallium” is an activator of the scintillator.

### [1. Configuration of Radiographic Image Detector]

A radiographic image detector 1 according to an embodiment of the present disclosure includes a scintillator panel 2 and other components. The scintillator panel 2 has a function of converting incident radiation R into light P having a different wavelength and emitting the light P, thereby generating a radiographic image corresponding to the radiation R.

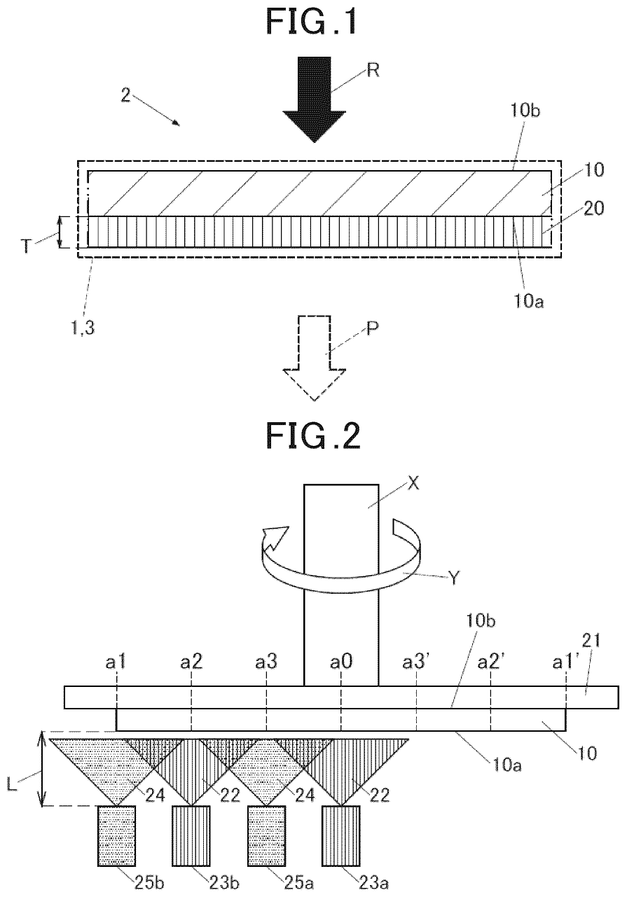

For example, as illustrated in FIG. 1, when radiation R in a wavelength region of X-rays is incident on the scintillator panel 2, the radiation R is converted into light P that is a type of electromagnetic wave with a wavelength in a range of 300 nm to 800 nm, including the visible light region and portions of the ultraviolet wavelength region and the infrared wavelength region.

The radiographic image detector 1 includes, as the other components, a housing 3 and a radiation detector housed inside the housing 3, and has the scintillator panel 2 as a component of the radiation detector. The radiation detector includes, for example, an element substrate on which photoelectric conversion elements are mounted as a component other than the scintillator panel 2, and the element substrate and the scintillator panel 2 are bonded to each other via an adhesive layer or the like. The element substrate has a function of detecting the light P converted by the scintillator panel 2 with the photoelectric conversion elements on the element substrate and converting the light P into electric charges.

Accordingly, a radiographic image based on the radiation R can be obtained. Detailed descriptions and illustrations of details of the other components related to the radiographic image detector 1, the radiation detector and the like, and the usage and the like of the radiographic image detector 1 will be omitted.

### [2. Configuration of Scintillator Panel]

As schematically shown in FIG. 1 and the like, the scintillator panel 2 in the radiographic image detector 1 of the present embodiment mainly includes a substrate 10 and a vapor deposition film layer 20 formed in a film shape on a substrate surface 10a of the substrate 10.

In the present embodiment, the vapor deposition film layer 20 is disposed on the substrate surface 10a corresponding to the back surface side of the substrate 10 (lower side of the sheet surface of FIG. 1), but not limited thereto. In the present embodiment, an incident surface 10b on which the radiation R is incident is further provided on a surface corresponding to the front surface side of the substrate 10 (upper side of the sheet surface of FIG. 1), the incident surface 10b being opposed to the substrate surface 10a of the substrate 10.

The radiation R is emitted from the incident surface 10b side, and the scintillator panel 2 receives the radiation R on the incident surface 10b side, and emits, from the vapor deposition film layer 20 side, the light P into which the radiation R having passed through the substrate 10 is converted while passing through the vapor deposition film layer 20, the light P including the visible light region and the like.

In FIGS. 1, 3, 5, 7, and 8, unless otherwise specified, an incident direction of the radiation R and an emitting direction of the light P from the scintillator panel 2 are the same. Therefore, in FIG. 1 and the like, the radiation R is incident and the light P is emitted (output) from the top of the sheet surface toward the bottom of the sheet surface.

The material forming the substrate 10 is not particularly limited. For example, the substrate 10 may be a glass substrate formed using glass of an inorganic material. Alternatively, the substrate 10 may be a polymer material substrate formed using an organic polymer material such as a cellulose acetate film, a polyester film, a polyethylene terephthalate film, or a polyimide (PI) film.

The shape of the substrate 10 is not particularly limited, and can be appropriately designed according to the shape and the like of the FPD to be employed. For example, the substrate 10 may have a substantially rectangular flat plate shape.

The thickness of the substrate 10 (in the vertical direction of the sheet surface of FIG. 1) is not particularly limited. It can be appropriately selected according to the permeability of the radiation R such as X-rays, the detection size of the radiation R in the radiographic image detector 1, and the like. For example, the substrate thickness of the substrate 10 is preferably 600 μm or less. Furthermore, in order that a vapor deposition film thickness T of the vapor deposition film layer 20 described later is as uniform as possible, the substrate surface 10a (and the incident surface 10b) of the substrate 10 is preferably formed of a smooth surface with few unevenness.

The vapor deposition film layer 20 of the scintillator panel 2 in the present embodiment is formed by vapor-depositing a phosphor component 22 in a film shape on the substrate surface 10a side of the substrate 10. In order to simplify the description, FIG. 1 shows the vapor deposition film thickness T of the vapor deposition film layer 20 from the substrate surface 10a being uniform, but it schematically shows the vapor deposition film thickness T, and actually, the vapor deposition film thickness T of the vapor deposition film layer 20 has unevenness in a minute range of about several tens of μm.

### [3. Vapor Deposition Image Related to Formation of Vapor Deposition Film Layer]

The vapor deposition film layer 20 can be produced, for example, in a vacuum vessel using a production apparatus based on the vapor deposition image shown in FIG. 2. That is, it is performed by using a support substrate 21 rotating in a predetermined rotation direction Y along the rotation axis X, and using the vapor phase growth method such as the vacuum vapor deposition method or the sputtering method while rotating the substrate 10 fixed to the support substrate 21. Thus, the vapor deposition film layer 20 is formed on the substrate surface 10a of the substrate 10 while the phosphor component 22 is crystal-grown under the vacuum atmosphere.

To be more specific, as shown in FIG. 2, in the formation of the vapor deposition film layer 20, first, the substrate 10 to be vapor-deposited is fixed to the support substrate 21 with the substrate surface 10a facing downward. Thus, the substrate 10 is axially rotated along the rotation axis X together with the support substrate 21.

A first phosphor evaporation source 23a for vaporizing and evaporating the phosphor component 22 is disposed to be spaced downward from the substrate surface 10a of the substrate 10 on an axial extension line of the central vapor deposition position a0, the axial extension line coinciding with the direction of the rotation axis X 10 being the rotation center of the substrate 10. In the present embodiment, cesium iodide (CsI) serving as a base material of the scintillator is used as the phosphor component 22 which is a raw material (vapor deposition material) for forming the vapor deposition film layer 20. A first activator evaporation source 25a for vaporizing and evaporating an activator component 24 is disposed on an axial extension line of a third vapor deposition position a3 spaced from the central vapor deposition position a0, which corresponds to the rotation center, in a radially outward direction (corresponding to the left direction on the sheet surface of FIG. 2). In the present embodiment, thallium (Tl) is used as the activator component 24 to be added to the phosphor component 22 and contained in the vapor deposition film layer 20.

As described above, cesium iodide can be generally used as the base material of the scintillator forming the vapor deposition film layer 20. Cesium iodide has a characteristic of efficiently converting radiation into light. In addition, the activator component 24 may be added in order to improve the performance of the scintillator. For example, as described above, the light emission efficiency of the scintillator can be improved by adding a small amount of thallium (Tl) to cesium iodide that is the base material of the scintillator.

A second phosphor evaporation source 23b and a second activator evaporation source 25b are arranged on axial extension lines to respectively face a second vapor deposition position a2 and a first vapor deposition position a1 that are spaced from the third vapor deposition position a3 in the radially outward direction. As a result, the four of the first phosphor evaporation source 23a, the first activator evaporation source 25a, the second phosphor evaporation source 23b, and the second activator evaporation source 25b are arranged at equal intervals along the radially outward direction from the central vapor deposition position a0, which is the rotation center of the substrate 10.

The arrangement order of the evaporation source 23a and so forth is not limited thereto, and for example, the first activator evaporation source 25a may be located on an axial extension line to face the central vapor deposition position a0. Furthermore, the number of the evaporation source 23a and so forth to be arranged is not limited thereto, and four or more evaporation sources may be provided.

As illustrated in FIG. 2, the evaporation source 23a and so forth are arranged at positions facing the substrate surface 10a. The evaporation source-substrate distance L between the evaporation source 23a and so forth and the substrate surface 10a can be, for example, in the range of 200 mm to 1000 mm. When the evaporation source-substrate distance L is long, in other words, when the evaporation source 23a and the like and the substrate surface 10a are far from each other, the use efficiency of the phosphor component 22 as the raw material decreases. Therefore, it is expected that the formation cost increases. On the other hand, when the evaporation source-substrate distance L is short, in other words, when the evaporation source 23a and the substrate surface 10a are close to each other, the film thickness distribution 30 (shown in FIG. 4) of the vapor deposition thickness T is more likely to be biased.

In the present embodiment, the evaporation source-substrate distance L can be set to be short. That is, it is possible to form the vapor deposition film layer 20 under conditions where the use efficiency of the phosphor component 22 is improved and the film thickness distribution 30 is allowed to a certain extent.

The support substrate 21 and the substrate 10 fixed to the support substrate 21 are rotated at a constant number of rotations in the rotation direction Y along the rotation axis X. The number of rotations of the support substrate 21 and the like along the rotation axis X is not particularly limited, and can be set to, for example, a condition used for forming a normal vapor deposition film layer 20 of about 1 to 15 rpm.

Such axial rotation of the substrate 10 causes momentary changes in the relative positions of the second phosphor evaporation source 23b, the first activator evaporation source 25a, and the second activator evaporation source 25b with respect to a particular point(s) (or range) on the substrate surface 10a of the substrate 10. Since the central vapor deposition position a0 on the substrate surface 10a is the rotation center, the distance between the first phosphor evaporation source 23a, which is positioned and arranged on the axial extension line of the central vapor deposition position a0, and the substrate surface 10a is fixed at the set evaporation source-substrate distance L, and the relative positional relationship does not change.

Next, in the formation of the vapor deposition film layer 20, while the substrate 10 is rotated together with the support substrate 21, the phosphor component 22 or the activator component 24 is vaporized and transpired from each of the first phosphor evaporation source 23a, the second phosphor evaporation source 23b, the first activator evaporation source 25a, and the second activator evaporation source 25b. Note that details of the configuration and the like of each of the evaporation source 23a and so forth, the vapor deposition method, and the like are conventionally known, and therefore detailed descriptions thereof are omitted. In the present embodiment, the vapor deposition image illustrated in FIG. 2 is performed under vacuum.

The phosphor component 22 vaporized and transpired from each of the evaporation source 23a and the like under a vacuum moves upward (corresponding to the upper side of the sheet surface of FIG. 2), and reaches the substrate surface 10a of the substrate 10, which is arranged above each of the evaporation source 23a and the like to face the same. Then, vapor deposition is performed on the substrate surface 10a, and crystals grow from the substrate surface 10a, whereby, for example, a film-form vapor deposition film layer 20 that covers the entire substrate surface 10a having a substantially rectangular shape is formed.

Note that the vapor deposition film thicknesses T corresponding to the thicknesses from the substrate surface 10a can be appropriately adjusted by vapor deposition conditions such as a preset vapor deposition time and vaporization amounts of the phosphor component 22 from the first phosphor evaporation source 23a and the second phosphor evaporation source 23b.

The vapor deposition film thickness T may be, for example, 500 μm or less. When the vapor deposition film thickness T exceeds 500 μm, the vapor deposition time for forming the vapor deposition film layer 20 becomes long, and it is necessary to increase the amount of evaporation of the phosphor component 22. Therefore, there is a possibility that the phosphor component 22 which is not used for vapor deposition increases, and it is expected that the use efficiency of the phosphor component 22 decreases and the cost for forming the vapor deposition film layer 20 increases.

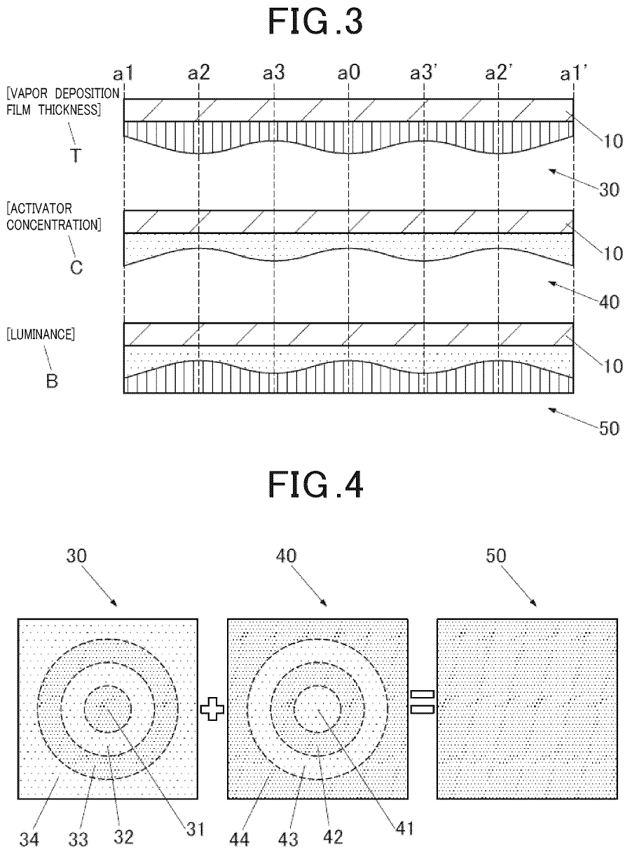

As described above, the luminance B (shown in FIG. 3 and the like) corresponding to the brightness of the light P per unit area is greatly influenced by the vapor deposition film thickness T of the vapor deposition film layer 20. However, in the vapor phase growth method as shown in FIG. 2, it is not easy to form the entire surface of the vapor deposition film layer 20 with a uniform vapor deposition film thickness T. In particular, in the case of forming the vapor deposition film layer 20 having a particularly large vapor deposition area, there is a possibility that the bias of the vapor deposition film thickness T (film thickness distribution 30) becomes remarkable.

The radiographic image detector 1 according to the present embodiment is characterized in that a certain degree of bias or the like is allowed for the vapor deposition film thickness T (film thickness distribution 30) of the vapor deposition film layer 20 constituting the scintillator panel 2. That is, the film thickness median value of the vapor deposition film thickness T of the entire surface of the vapor deposition film layer 20 is calculated, and the vapor deposition film thickness T is allowed to be a thickness of the calculated film thickness median value ±10%.

### <Measurement of Vapor Deposition Film Thickness>

The vapor deposition film thickness T of the vapor deposition film layer 20 is measured with an overcurrent film thickness meter (ISOSCOPE MP10E: manufactured by Fisher Instrument) by providing a lattice constituted by lines at equal intervals vertically and horizontally on the vapor deposition film layer 20, at nine or more intersections as measurement points. Based on the obtained measurement result, the film thickness median value is calculated.

For example, when the obtained film thickness median value of the vapor deposition film thickness T of the vapor deposition film layer 20 is 400 μm, the vapor deposition film thickness T in the vapor deposition film layer 20 can be set to 360 μm as the minimum value and 440 μm as the maximum value. That is, in the present embodiment, the vapor deposition film layer 20 is allowed to have an allowable error of ±40 μm with respect to the film thickness median value. Thus, the formation conditions (vapor deposition conditions) can be more relaxed than in the formation of a vapor deposition film layer in a conventional scintillator panel. As a result, the formation of the vapor deposition film layer 20 becomes easy, and the possibility of reducing the use efficiency of the phosphor component 22 is reduced. That is, the cost for forming the vapor deposition film layer 20 is not increased.

The vapor deposition film layer 20 formed with the above-described vapor deposition image may vary in the vapor deposition film thickness T with respect to the entire layer surface, in other words, a large bias in the film thickness distribution 30.

To be more specific, according to the vapor deposition image related to the formation of the vapor deposition film layer 20 shown in FIG. 2, the first phosphor evaporation source 23a is disposed to face the central vapor deposition position a0 of the substrate surface 10a of the substrate 10 positioned on the axial extension line of the rotation axis X.

In this case, the phosphor component 22 vaporized and transpired from the first phosphor evaporation source 23a is most likely to be vapor-deposited on the substrate surface 10a in the vicinity of the central vapor deposition position a0 closest to the first phosphor evaporation source 23a. Although the substrate 10 itself rotates, the central vapor deposition position a0 is the rotation center, and the relative positional relationship between the central vapor deposition position a0 and the first phosphor evaporation source 23a hardly changes.

As a result, the central vapor deposition position a0 has the largest vapor deposition amount of the phosphor component 22. Therefore, the vapor deposition film thickness T is thick. On the other hand, the vapor deposition amount gradually decreases as the distance from the central vapor deposition position a0 increases. Therefore, the vapor deposition film thickness T is thinner than that at the central vapor deposition position a0 (shown in FIG. 3).

Furthermore, according to the vapor deposition image of FIG. 2, the second phosphor evaporation source 23b is arranged at a position facing the second vapor deposition position a2 separated from the central vapor deposition position a0 in the radially outward direction. Thus, the phosphor component 22 vaporized and transpired from the second phosphor evaporation source 23b is more vapor-deposited on the substrate surface 10a at the second vapor deposition position a2 closest to the second phosphor evaporation source 23b.

Since the substrate 10 is rotating along the rotation axis X, the second vapor deposition position a2 on the substrate surface 10a changes from moment to moment. Therefore, a concentric part having a large vapor deposition film thickness T is formed at a position corresponding to the second vapor deposition position a2 centering on the central vapor deposition position a0.

In an imaginary sectional view from a side of the vapor deposition film layer 20 (from the front to the depth of the sheet surface of FIG. 2), the vapor deposition film thickness T is thickest at the central vapor deposition position a0, the second vapor deposition position a2, and an opposite second vapor deposition position a2′ opposite to the second vapor deposition position a2 across the central vapor deposition position a0 (shown in FIG. 3). That is, as shown in the virtual sectional view of FIG. 3, the vapor deposition film thickness T in the vapor deposition film layer 20 changes in a wave-like manner.

In the vapor deposition image in FIG. 2, the first activator evaporation source 25a and the second activator evaporation source 25b are disposed to face the third vapor deposition position a3 and the first vapor deposition position a1, respectively, on the substrate 10. Therefore, the activator concentration C is such that a large amount of the activator component 24 is vapor-deposited at the first vapor deposition position a1 and the third vapor deposition position a3 where the second activator evaporation source 25b and the first activator evaporation source 25a are closest to the substrate surface 10a, respectively.

That is, in the imaginary sectional view from the side of the vapor deposition film layer 20, the activator concentration C is thickest at the first vapor deposition position a1, the third vapor deposition position a3, and an opposite first vapor deposition position a1′ and an opposite third vapor deposition position a3′ respectively opposite to the first vapor deposition position a1 and the third vapor deposition position a3 across the central vapor deposition position a0 (shown in FIG. 3). That is, as illustrated in the imaginary sectional view of FIG. 3, in the formed vapor deposition film layer 20, the activator concentration C in the vapor deposition film layer 20 changes in a wave-like manner substantially opposite in phase to the vapor deposition film thickness T.

### <Measurement of Activator Concentration>

The activator concentration of the activator component 24 contained in the vapor deposition film layer 20 is determined as follows. A vapor deposition film (phosphor) is cut out from the vapor deposition film layer 20, centering on the measurement point at which the above-described measurement of the vapor deposition film thickness T is performed, and then the vapor deposition film is pulverized to measure the activator concentration. The vapor deposition film thus cut out is subjected to the measurement of the activator concentration by inductively-coupled-plasma optical emission spectrometry (ICP-OES), fluorescent X-ray analysis, or the like. When ICP-OES is used, the vapor deposition film is mixed with concentrated hydrochloric, heated to dryness, further mixed with aqua regia, heated to dissolution, and appropriately diluted with ultrapure water. With this as a measurement sample, measurement is performed with an ICP optical emission spectrometer (SPS3100: manufactured by Seiko Instruments Inc) set.

Further, in the case of measuring the activator concentration of ½ portion on the X-ray irradiation side in the film thickness direction, cutting is performed from the X-ray irradiation side of the vapor deposition film until the film thickness of ½ is obtained, and the obtained measurement sample is used to measure the activator concentration in the same manner as the above.

In this case, cutting may be performed from the surface on the side opposite to the X-ray irradiation side so that the film thickness becomes ½, and the remaining portion may be further cut. In addition, in the case where the vapor deposition film is fragile and cutting is difficult, cutting may be performed after the vapor deposition film is filled with a resin.

The activator component 24 is added in a slight amount to the phosphor component 22, and the amount of the activator component 24 (activator concentration C) does not affect the vapor deposition film thickness T.

As described above, in the vapor deposition film layer 20 of the scintillator panel 2 according to the present embodiment, the vapor deposition film thickness T of the vapor deposition film layer 20 and the activator concentration C of the activator component 24 correlate with each other in the imaginary sectional view. In addition, when this is replaced on a plane, the film thickness distribution 30 of the vapor deposition film layer 20 and the activator concentration distribution 40 correlate with each other.

On the other hand, the luminance B corresponding to the brightness per unit area of the light P generated by the conversion of the radiation R by the scintillator panel 2 is greatly affected by the vapor deposition film thickness T of the vapor deposition film layer 20. For example, in the film thickness distribution 30 illustrated in FIG. 4, in a region where the vapor deposition film thickness T is thick (thick film region 31), the luminance of the thick film region 31 is high (bright). On the other hand, in a region where the vapor deposition film thickness T is thin (thin film region 32), the luminance of the thin film region 32 is low (dark).

The luminance B of the scintillator panel 2 is also affected by the activator concentration C of the activator component 24 contained in the vapor deposition film layer 20. For example, in the activator concentration distribution 40 illustrated in FIG. 4, in a region having a high activator concentration C (high concentration region 42), the luminance B of the high concentration region 42 is high (bright). On the other hand, in a region where the activator concentration C is low (low concentration region 41), the luminance B of the low concentration region 41 is low (dark).

In FIG. 4, the film thickness distribution 30 and the activator concentration distribution 40 are schematically shown for the vapor deposition film layer 20 formed by the vapor deposition image of FIG. 2. Furthermore, in FIG. 4, in the film thickness distribution 30, the thick film region 31 corresponding to the region where the vapor deposition film thickness T is thick (large) is darkly hatched, and the thin film region 32 corresponding to the region where the vapor deposition film thickness T is thin (small) is lightly hatched. On the other hand, in the activator concentration distribution 40, the low concentration region 41 corresponding to the region where the activator concentration C is low (thin) is lightly hatched, and the high concentration region 42 corresponding to the region where the activator concentration C is high (thick) is darkly hatched.

In the scintillator panel 2 according to the present embodiment, the vapor deposition film thickness T of the vapor deposition film layer 20 is allowed to be within a range of 10% with respect to the film thickness median value. In addition, focusing on the activator concentration C and the activator concentration distribution 40 of the activator component 24 in the vapor deposition film layer 20, which affect the luminance B of the light P, the film thickness distribution 30 related to the vapor deposition film thickness T and the activator concentration distribution 40 related to the activator concentration C correlate with each other. As a result, the luminance distribution 50 of the luminance B of the finally converted light P becomes uniform in the entire surface of the vapor deposition film layer 20 (shown in FIG. 3 and FIG. 4).

### <Luminance Measurement>

The luminance is measured by emitting X-rays at a voltage of 80 kVp to a radiographic image detector in which a scintillator panel is disposed, and using signal values of pixels acquired by the radiographic image detector. For the median value of the FPD luminance, the median value of the signals of the pixels present in the entire effective image region is defined as the luminance median value of the radiographic image detector.

In other words, two conditions (parameters) of the vapor deposition film thickness T and the activator concentration C in the vapor deposition film layer 20 are in what is called a “trade-off” relationship. As a result, even if there is a condition that the luminance decreases (becomes dark) on one side, a condition that the luminance increases (becomes bright) on the other side is satisfied. As a result, the vapor deposition film layer 20 can be formed without making the film-forming conditions of the vapor deposition film layer 20, particularly the conditions for making the vapor deposition film thickness T uniform, severe, and the luminance B of the light P finally obtained can be made uniform over the entire layer surface by adjusting the activator concentration C.

Hereinafter, the correlation between the film thickness distribution 30 and the activator concentration distribution 40 will be described in detail. In the thick film region 31 where the vapor deposition film thickness T is thicker than a predefined reference film thickness value in the film thickness distribution 30 of the vapor deposition film layer 20, the activator concentration C of the region (low concentration region 41) of the activator concentration distribution 40 corresponding to the thick film region 31 is set lower than a predefined reference concentration value. As a result, the two characteristics of the thick film region 31 having the thick vapor deposition film thickness T and the low concentration region 41 having the low activator concentration C corresponding thereto are superposed on each other, and thus the luminance distribution 50 becomes in-plane uniform in the end.

Similarly, in the thin film region 32 where the vapor deposition film thickness T is thinner than the predetermined reference film thickness value in the film thickness distribution 30 of the vapor deposition film layer 20, the activator concentration C of the region (high concentration region 42) of the activator concentration distribution 40 corresponding to the thin film region 32 is set higher than the predetermined reference concentration value. As a result, the two characteristics of the thin film region 32 having the thin vapor deposition film thickness T and the high concentration region 42 having the high activator concentration C corresponding thereto are superposed on each other, and thus the luminance distribution 50 becomes in-plane uniform in the end.

The vapor deposition film layer 20 in the present embodiment has a thick film region 33 outside the thin film region 32 of the film thickness distribution 30 described above, and has a thin film region 34 outside the thick film region 33. Similarly, it has a low concentration region 43 outside the high concentration region 42 of the activator concentration distribution 40, and has a high concentration region 44 outside the low concentration region 43.

Thus, the film thickness distribution 30 of the vapor deposition film thickness T and the activator concentration distribution 40 of the activator concentration C related to the luminance B correlate with each other over the entire surface of the vapor deposition film layer 20. As a result, the obtained luminance B and luminance distribution 50 related to the luminance B can be uniform over the entire layer surface. That is, in FIG. 3, the luminance B is expressed by a certain height from the substrate 10. In FIG. 4, the luminance distribution 50 is uniformly hatched.

In the radiographic image detector 1 of the present embodiment, the vapor deposition film layer 20 of the scintillator panel 2 may use cesium iodide (CsI) as the phosphor component 22 and thallium (Tl) as the activator component 24. Thus, the scintillator panel 2 having the vapor deposition film layer 20 of activated cesium iodide (CsI:Tl) can be formed. Note that the combination of the phosphor component 22 and the activator component 24 is not limited thereto, and any other known phosphor component 22 and activator component 24 may be used in appropriate combination.

The reference film thickness value serving as a reference of the vapor deposition film thickness T in the film thickness distribution 30 is a predefined numerical value, and for example, a film thickness median value calculated based on the vapor deposition film thickness T over the entire layer surface can be used. Meanwhile, the reference concentration value serving as a reference of the activator concentration C in the activator concentration distribution 40 is a predefined numerical value, and for example, an activator concentration median value calculated based on the activator concentration C over the entire surface of the vapor deposition film layer 20 can be used.

This makes it possible to define the correlation between the film thickness distribution 30 and the activator concentration distribution 40 with the film thickness median value and/or the activator concentration median value over the entire surface of the vapor deposition film layer 20 as the reference(s). Note that the reference film thickness value and the reference concentration value are not limited thereto, and average values over the entire layer surface or predetermined specific values may be used.

Further, regarding the vapor deposition film layer 20, the film thickness median value may be in the range of 150 μm to 800 μm, and the activator concentration C may be in the range of 0.1 to 1.5 mol %. By adopting such a configuration, the luminance B of the light P by the scintillator panel 2 can be within ±5% with respect to the luminance median value over the entire surface of the vapor deposition film layer 20. Thus, the scintillator panel 2 having the in-plane uniform luminance distribution 50 can be formed while the formation cost of the vapor deposition film layer 20 is suppressed.

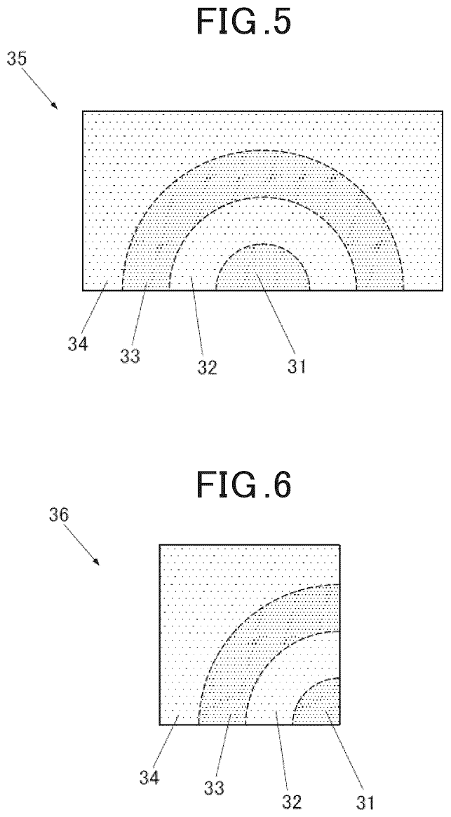

In the scintillator panel of the present disclosure, the film thickness distribution of the vapor deposition film layer is not limited to the already-illustrated film thickness distribution 30 in the shape of concentric circles (shown in FIG. 4). For example, it may be a film thickness distribution 35 in the shape of concentric semicircles (shown in FIG. 5) obtained by dividing the concentric circular film thickness distribution 30 in the diameter direction. Alternatively, the film thickness distribution may be a film thickness distribution 36 in the shape of concentric quadrants (shown in FIG. 6) obtained by dividing the concentric semicircular film thickness distribution 35 in half.

In the formation of the vapor deposition film layer 20, based on the vapor deposition image illustrated in FIG. 2, the vapor deposition film layer 20 having the concentric circular film thickness distribution 30 may be formed with a relatively large vapor deposition area, and then this vapor deposition film layer 20 may be divided into two or four to be used for the scintillator panel. Therefore, a vapor deposition film layer having the concentric semicircular film thickness distribution 35 as shown in FIG. 5 or the concentric quadrantal film thickness distribution 36 as shown in FIG. 6 may be used. Such a case has an activator concentration distribution in which the activator concentration C corresponding to the film thickness distribution 30, 35 or 36 is distributed.

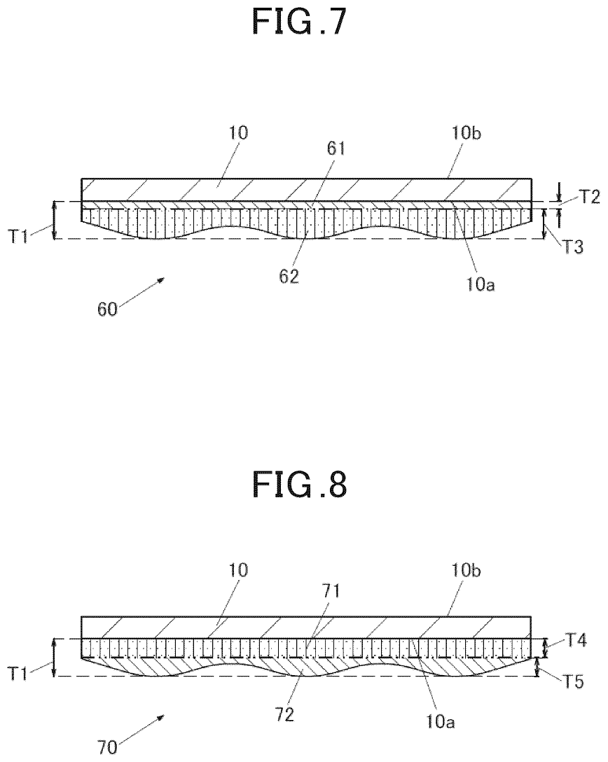

Furthermore, as illustrated in FIG. 7, a vapor deposition film layer 60 of another configuration example of the present embodiment may have a first vapor deposition film layer 61 and a second vapor deposition film layer 62. In the first vapor deposition film layer 61, the vapor deposition film thickness T2 from the substrate surface 10a is within 10% with respect to the maximum film thickness T1 from the substrate surface 10a. Meanwhile, the second vapor deposition film layer 62 is stacked on the first vapor deposition film layer 61 and has a vapor deposition film thickness T3 from the first vapor deposition film layer 61 of more than 10% up to the maximum film thickness T1. In the vapor deposition film layer 60, the first vapor deposition film layer 61 does not contain the activator component 24. That is, the activator concentration C in the first vapor deposition film layer 61 is 0%. The absence of the activator component 24 in the first vapor deposition film layer 61 improves the crystal independence of the phosphor component 22 (CsI) in what is called a “root portion” close to the substrate surface 10a in the direction of the vapor deposition film thickness T (shown in FIG. 2) of the vapor deposition film layer 60.

Alternatively, as illustrated in FIG. 8, a vapor deposition film layer 70 of another configuration example of the present embodiment may have a third vapor deposition film layer 71 and a fourth vapor deposition film layer 72. In the third vapor deposition film layer 71, the vapor deposition film thickness T4 from the substrate surface 10a is within 50% with respect to the maximum film thickness T1 from the substrate surface 10a. Meanwhile, the fourth vapor deposition film layer 72 is stacked on the third vapor deposition film layer 71 and has a vapor deposition film thickness T5 from the third vapor deposition film layer 71 of more than 50% up to the maximum film thickness T1. In the vapor deposition film layer 70, at least 70% of the activator component 24 with respect to the total amount of the activator component 24 is contained in the third vapor deposition film layer 71. With the third vapor deposition film layer 71 having such a configuration, the activator component 24 present at the “root portion” close to the substrate surface 10a greatly contributes to the luminance B of the vapor deposition film layer 70. In addition, since most of the activator component 24 is contained in the third vapor deposition film layer 71 having a film thickness of 50% or less from the substrate surface 10a, X-rays incident from the substrate surface 10a can be more efficiently converted into visible light. Furthermore, when a large amount of the activator component 24 is present on the surface (fourth vapor deposition film layer 72 side) of the vapor deposition film layer 70, the coloration of the vapor deposition film layer 70 tends to be relatively large, and the absorption ratio of visible light increases. Thus, there is a possibility that the luminance decreases, and therefore it is preferable that 70% or more of the activator component 24 is present in the third vapor deposition film layer 71 with respect to the total amount thereof.

### EXAMPLES

Hereinafter, the present disclosure will be described based on examples, but the present disclosure is not limited thereto.

### <1> Formation of Vapor Deposition Film Layer

The vapor deposition film layer of example 1 was obtained using a manufacturing apparatus according to the vapor deposition image schematically illustrated in FIG. 2. First, cesium iodide (CsI) as a phosphor component and thallium (Tl) as an activator component were vapor-deposited on one surface (substrate surface) of a polyimide resin sheet (thickness: 125 μm) to be a substrate, to form a vapor deposition film layer.

Specifically, a substrate to be subjected to vapor deposition was placed on a support substrate provided with a support substrate rotating mechanism in a vacuum vessel. Next, the phosphor component and the activator component as vapor deposition materials were filled in evaporation source crucibles (evaporation sources), and were arranged in the vicinity of the inside of the vacuum vessel, at the center of a center line (rotation axis) perpendicular to the support substrate, and on the circumference of a circle having the center (see FIG. 2). At this time, the distance between the substrate and the evaporation sources (evaporation source-substrate distance) was adjusted to 400 mm, and the distance between the center line (rotation axis) perpendicular to the substrate and the evaporation sources was adjusted to 400 mm. Subsequently, the inside of the vacuum vessel was once evacuated, an Ar gas was introduced to adjust the vacuum degree to 0.1 Pa, and then the temperature of the substrate was held at 30° C. while the substrate was being rotated at a speed of 10 rpm.

Next, the temperature in the evaporation source crucibles was increased to 700° C. by resistive heating, vapor deposition of the phosphor component and the activator component was started from a total of four evaporation sources in a state where the substrate was being rotated, and the vapor deposition was completed when the vapor deposition film thickness of the vapor deposition film layer became 400 μm.

Thereafter, the vapor deposition film layer (phosphor layer) was placed in a protective layer bag (protective layer bag made of a laminated film of polyethylene terephthalate (PET) and casting polypropylene (CPP)) in dry air, and the peripheral edge was sealed by fusion using an impulse sealer under reduced pressure to obtain a vapor deposition film layer having a structure in which the phosphor layer was sealed.

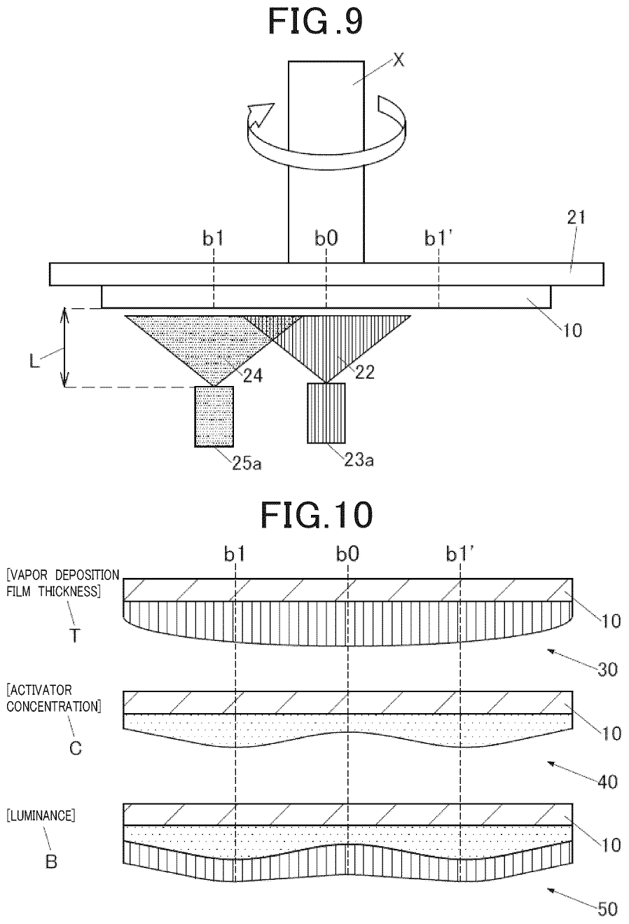

Vapor deposition film layers of comparative example 1 and 2 were obtained using the manufacturing apparatus according to the vapor deposition image schematically shown in FIG. 9. The vapor deposition film layer of example 1 was obtained using a total of four evaporation sources, whereas the vapor deposition film layers of comparative example 1 and 2 were obtained using a total of two evaporation sources as shown in FIG. 9. Changes in vapor deposition film thickness, activator concentration, and luminance in the vapor deposition film layers of comparative example 1 and 2 are schematically illustrated in FIG. 10.

Note that the evaporation source-substrate distance in the vapor deposition film layer of comparative example 1 was set to be 400 mm as in example 1. On the other hand, the evaporation source-substrate distance in the vapor deposition film layer of comparative example 2 was set to 800 mm different from the vapor deposition film layers of example 1 and comparative example 1. That is, the vapor deposition film layer of example 1 and the vapor deposition film layer of comparative example 1 were different in the number of evaporation sources that were disposed to face the substrate surface, and the other conditions were the same, whereas the vapor deposition film layer of comparative example 1 and the vapor deposition film layer of comparative example 2 were different only in the evaporation source-substrate distance, and the other conditions were the same.

### [Table I]

TABLE I

| | | | VAPOR | | | | |
|---|---|---|---|---|---|---|---|
| | | EVAPORATION | DEPOSITION | | | | |
| | VAPOR | SOURCE- | FILM | ACTIVATOR | | | |
| | DEPOSITION | SUBSTRATE | THICKNESS/ | CONCENTRATION/ | | | |
| | IMAGE | DISTANCE/mm | μm | mol % | *1 | *2 | *3 |
| EXAMPLE 1 | FIGS. 2, 3 | 400 | 400 ± 40 | THICK FILM | OK | OK | OK |
| | | | | REGION: | 10~12% | WITHIN | |
| | | | | 0.2~0.4 | | ±5% | |
| | | | | THIN FILM | | | |
| | | | | REGION: | | | |
| | | | | 0.5~0.8 | | | |
| COMPARATIVE | FIGS. 9, 10 | 400 | 400 ± 40 | 0.5~0.8 | OK | NG | NG |
| EXAMPLE 1 | | | | | 10~12% | EXCEED | |
| | | | | | | ±5% | |
| COMPARATIVE | FIGS. 9, 10 | 800 | 400 ± 20 | 0.5~0.8 | NG | OK | NG |
| EXAMPLE 2 | | | | | 4~6% | WITHIN | |
| | | | | | | ±5% | |

*1: EVALUATION OF USE EFFICIENCY OF PHOSPHOR COMPONENT
*2: EVALUATION ON LUMINANCE DISTRIBUTION
*3: OVERALL EVALUATION

The obtained vapor deposition film layer of example 1 was adjusted such that the activator concentration in the region (low concentration region) corresponding to the thick film region was in the range of 0.2 to 0.4 mol % and the activator concentration in the region (high concentration region) corresponding to the thin film region was in the range of 0.5 to 0.8 mol %.

On the other hand, in the case of comparative examples 1 and 2, as illustrated in FIG. 10, in the imaginary side sectional view, the vapor deposition film thickness T is thickest at the central vapor deposition position b0 serving as the rotation center, and the vapor deposition film thickness T gradually decreases in the radially outward direction. Regarding the activator concentration C, since the first activator evaporation source 25a is disposed on the axial extension line to face the first vapor deposition position b1, there is a region having a high activator concentration C concentrically around the central vapor deposition position b0. Therefore, even if these are added together, the luminance B does not become uniform, and the luminance distribution of the light P is biased.

### <2> ½ Film Thickness Range of Activator Concentration

As specifically shown in FIG. 8, the vapor deposition film layers of example 1 and comparative examples 1 and 2 each have a third vapor deposition film layer having a vapor deposition film thickness from the substrate surface of 50% or less of the maximum film thickness T1. At least 70% of the total amount of the activator component contained in each of the vapor deposition film layers is contained in the third vapor deposition film layer.

### <3> Evaluation of Use Efficiency of Phosphor Component

The use efficiency of the phosphor component in the obtained vapor deposition film layers according to example 1 and comparative examples 1 and 2 was evaluated based on the following evaluation criteria. According to this, the following evaluation was obtained: the use efficiency of the phosphor component is satisfactory (=OK) in the vapor deposition film layers of example 1 and comparative example 1, in which the evaporation source-substrate distance was short. On the other hand, the vapor deposition film layer of comparative example 2, in which the evaporation source-substrate distance was far, was evaluated as having poor use efficiency of the phosphor component (=NG).

### <Evaluation Criteria for Use Efficiency of Phosphor Component>

Regarding the use efficiency of the phosphor component, the weights of the scintillator matrix (cesium iodide) and the activator used in the evaporation source before and after vapor deposition were measured with an electronic balance (GF-6100: manufactured by A&D Company, Limited), and the weight X (g) of the scintillator material used for evaporation was measured. Next, the weight Y (g) of the scintillator after vapor deposition was measured. Based on the obtained measurement results, the ratio of the weight Y (g) to the weight X (g) was defined as the use efficiency. A case where the use efficiency of the weight Y (g) to the weight X (g) was 10% or more was evaluated as satisfactory (=OK), and a case where it was less than 10% was evaluated as unsatisfactory (=NG).

### <4> Luminance Distribution Evaluation

The luminance distributions of the obtained vapor deposition film layers according to example 1 and comparative examples 1 and 2 were evaluated based on the following evaluation criteria. According to this, in the vapor deposition film layers of example 1 and comparative example 2, evaluation of good (=OK) in which the luminance distribution was uniform was obtained. On the other hand, the vapor deposition film layer of comparative example 1 was evaluated as unsatisfactory (=NG) because of uneven luminance distribution.

### <Evaluation Criteria for Luminance Distribution>

As an example, in an image having an effective image region of 420 mm×420 mm, the entire effective image region was divided into regions of interest (ROIs) each having 100 pixels×100 pixels, and the median value of each ROI was calculated. The maximum value ROI_MAX and the minimum value ROI_MIN among the calculated median values of the ROIs were divided by the median value of the luminance of the radiographic image detector (FPD luminance) to obtain the luminance distribution. Then, a case where the value of ROI_MAX−FPD luminance median/FPD luminance median value was 5% or less and the value of ROI_MIN−FPD/FPD luminance median value was-5% or more was evaluated as satisfactory (=OK), and the other cases were evaluated as unsatisfactory (=NG).

### <5> Overall Evaluation

As illustrated in the evaluation results, it was demonstrated that, in the radiographic image detector according to the present disclosure, a vapor deposition film layer having satisfactory use efficiency of a phosphor component and a satisfactory luminance distribution can be obtained by correlating the film thickness distribution and the activator concentration distribution of the vapor deposition film layer constituting the scintillator panel. The radiographic image detector according to the present disclosure is particularly suitable for a scintillator panel including a vapor deposition film layer having a large vapor deposition area. That is, according to the present disclosure, a radiographic image detector including a scintillator panel having a uniform luminance distribution can be provided. In a case where both of the evaluation of the use efficiency of the phosphor component and the evaluation of the luminance distribution were satisfactory, the overall evaluation was satisfactory (=OK), and in a case where at least one of the evaluation of the use efficiency of the phosphor component and the evaluation of the luminance distribution was unsatisfactory, the overall evaluation was unsatisfactory (=NG).

Although embodiments of the present disclosure have been described and illustrated in detail, the disclosed embodiments are made for purposes of illustration and example only and not limitation. The scope of the present disclosure should be interpreted by terms of the appended claims.

What is claimed is:

1. A radiographic image detector comprising:
a scintillator panel including:
a substrate; and
on a substrate surface of the substrate, a vapor deposition film layer in which a phosphor component is vapor-deposited in a film form together with an activator component,
wherein a vapor deposition film thickness corresponding to a thickness of the vapor deposition film layer from the substrate surface is set to a thickness within ±10% with respect to a film thickness median value over an entire surface of the vapor deposition film layer, and
wherein a film thickness distribution related to the vapor deposition film thickness and an activator concentration distribution related to an activator concentration of the activator component in the vapor deposition film layer correlate with each other.

2. The radiographic image detector according to claim 1, wherein the correlation between the film thickness distribution and the activator concentration distribution is set such that:
in a case where the vapor deposition film thickness in a specific region of the vapor deposition film layer is larger than a reference film thickness value, the activator concentration in the specific region is set to be lower than a reference concentration value; and
in a case where the vapor deposition film thickness in the specific region of the vapor deposition film layer is smaller than the reference film thickness value, the activator concentration in the specific region is set to be higher than the reference concentration value.

3. The radiographic image detector according to claim 1,
wherein as the phosphor component, cesium iodide is used, and
wherein as the activator component, thallium is used.

4. The radiographic image detector according to claim 2,
wherein as the reference film thickness value, the film thickness median value is used, and
wherein as the reference concentration value, an activator concentration median value of the activator concentration over the entire surface of the vapor deposition film layer is used.

5. The radiographic image detector according to claim 1,
wherein the film thickness median value of the vapor deposition film layer is 150 to 800 μm,
wherein the activator concentration in the vapor deposition film layer is 0.1 to 1.5 mol %, and
wherein a luminance of the scintillator panel having the vapor deposition film layer is within ±5% with respect to a luminance median value over the entire surface of the vapor deposition film layer.

6. The radiographic image detector according to claim 1,
wherein the film thickness distribution is at least one of a concentric circular shape, a concentric semicircular shape, or a concentric quadrantal shape, and
wherein the activator concentration distribution corresponds to the film thickness distribution.

7. The radiographic image detector according to claim 1, wherein the vapor deposition film layer includes:
a first vapor deposition film layer whose vapor deposition film thickness from the substrate surface is 10% or less with respect to a maximum film thickness from the substrate surface; and
a second vapor deposition film layer that is stacked on the first vapor deposition film layer and whose vapor deposition film thickness from the first vapor deposition film layer is more than 10% up to the maximum film thickness,
wherein the first vapor deposition film layer does not contain the activator component.

8. The radiographic image detector according to claim 1, wherein the vapor deposition film layer includes:
a third vapor deposition film layer whose vapor deposition film thickness from the substrate surface is 50% or less with respect to a maximum film thickness from the substrate surface; and
a fourth vapor deposition film layer that is stacked on the third vapor deposition film layer and whose vapor deposition film thickness from the third vapor deposition film layer is more than 50% up to the maximum film thickness,
wherein at least 70% of the activator component with respect to a total amount of the activator component contained in the vapor deposition film layer is contained in the third vapor deposition film layer.
